(19) United States
(12) Patent Application Publication
(10) Pub. No.: US 2026/0035782 A1
(43) Pub. Date: Feb. 5, 2026

(54) METHOD AND SYSTEM FOR DEPOSITING METAL CARBIDE ON A SUBSTRATE

(71) Applicant: ASM IP Holding B.V., Almere (NL)

(72) Inventors: Charles Dezelah, Helsinki (FI); Petro Deminskyi, Espoo (FI); Qi Xie, Shanghai (CN)

(21) Appl. No.: 19/284,207

(22) Filed: Jul. 29, 2025

Related U.S. Application Data
(60) Provisional application No. 63/677,883, filed on Jul. 31, 2024.

(51) Int. Cl. C23C 16/32; C23C 16/455; C23C 16/52

(52) U.S. Cl. CPC C23C 16/32; C23C 16/45544; C23C 16/45553; C23C 16/52

(57) ABSTRACT

A method and system for depositing metal carbide on a substrate is provided. The method may include, providing a substrate in a reaction chamber, providing a first precursor comprising a metal alkyl provided with a first metal in the reaction chamber, providing a second precursor comprising a halogenated hydrocarbon in the reaction chamber, and providing a third precursor comprising a second metal different than the first metal in the reaction chamber. A metal carbide layer may be formed on the substrate.

### CROSS-REFERENCE TO RELATED APPLICATION(S)

This application claims the benefit of U.S. Provisional Application 63/677,883 filed on Jul. 31, 2024, the entire contents of which are incorporated herein by reference.

### FIELD OF INVENTION

The present disclosure generally relates to methods and systems suitable for forming a layer on a substrate and to structures including the layer. More particularly, the disclosure relates to methods and systems for forming a metal carbide layer on a substrate and to structures formed using the methods and systems.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques may face significant challenges for future technology nodes. For example, one challenge may be finding suitable dielectric stacks that form an insulating barrier between a gate and a channel of a field effect transistor. One problem in this regard may be controlling the threshold voltage of field effect transistors.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of forming structures including metal carbide containing layers, to structures and devices formed using such methods, and to systems for performing the methods and/or for forming the structures and/or devices. The metal carbide containing layers can be used in a variety of applications, including reducing power consumption in integrated circuits. The methods can comprise a cyclical deposition process. The cyclical deposition process can include one or more of an atomic layer deposition process and a cyclical chemical vapor deposition process. The cyclical deposition process can include a thermal process—i.e., a process that does not use plasma-activated species. In some cases, a precursor can be exposed to a plasma to form activated precursor species, e.g. radicals and/or ions.

Described herein is a method for depositing a metal carbide containing layer on a substrate. The method comprises providing a substrate within a reaction chamber. The method may further comprise:
providing a first precursor comprising a metal alkyl comprising a first metal in the reaction chamber;
providing a second precursor comprising a halogenated hydrocarbon in the reaction chamber; and
providing a third precursor comprising a second metal different than the first metal in the reaction chamber and thereby forming a metal carbide layer on the substrate in the reaction chamber. The substrate may comprise a surface layer. The method may further comprise depositing a metal carbide containing layer onto the surface layer by means of a cyclical deposition process. The cyclical deposition process may comprise one or more cycles. A cycle may comprise providing three precursors. A cycle may comprise two precursor with different metals. The precursors may be provided in pulses separated in time in the reaction chamber in an atomic layer deposition system. The precursors may be provided continuous in a spatial atomic layer deposition system which uses a spatial separation of the precursors. A metal carbide containing layer may be formed on the substrate with the methods. The method for depositing a metal carbide containing layer on a substrate can be used for forming a structure. The structure may be used to form a metal gate electrode for a CMOS, e.g. n-MOS or p-MOS, transistor.

Further described herein is a system for depositing metal carbide, the system comprising:
a reaction chamber,
a first gas source for providing a first gas comprising a metal alkyl provided with a first metal in the reaction chamber;
a second gas source for providing a second precursor comprising a halogenated hydrocarbon in the reaction chamber;
a third precursor gas source for providing a third precursor comprising a second metal different than the first metal in the reaction chamber; and,
a controller to control the flow of gas from the first, second and third precursor gas source to the reaction chamber. The system may be controlled to deposit a metal carbide containing layer on a substrate in the reaction chamber.

Further described herein is a structure comprising a stack of layers, in the following order: a first conductive layer, a metal carbide containing layer, and a second conductive layer. The structure may be used as an electrode. The method comprises providing a substrate within a reaction chamber. The substrate comprises a gate dielectric. The method further comprises depositing a first conductive layer on the gate dielectric, and subsequently depositing a metal carbide containing layer onto the first conductive layer by means of a cyclical deposition process. The cyclical deposition process comprises one or more cycles. A cycle may comprise three precursor pulses. The method may comprise providing a first precursor comprising a metal alkyl provided with a first metal. The method may comprise providing a second precursor comprising a halogenated hydrocarbon. The method may comprise providing a third precursor comprising a second metal different than the first metal precursor. Then, the method comprises depositing a second conductive layer on the metal carbide. Thus, a structure function as an electrode is formed on the substrate. The electrode comprises the first conductive layer, the metal carbide containing layer, and the second conductive layer.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates a method in accordance with exemplary embodiments of the disclosure.

FIG. 3 illustrates a structure in accordance with exemplary embodiments of the disclosure.

FIG. 4 illustrates a structure in accordance with exemplary embodiments of the disclosure.

FIG. 5 illustrates a structure in accordance with exemplary embodiments of the disclosure.

FIG. 6 illustrates a system for performing the method of FIGS. 1 to 2 to create the structures of FIGS. 3 to 5 in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for forming structures, such as gate dielectrics or portions thereof for field effect transistors. Exemplary methods can be used to, for example, form CMOS devices, or portions of such devices. However, unless noted otherwise, the invention is not necessarily limited to such examples.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas.

In some cases, the term “precursor” can refer to a compound that participates in the chemical reaction that produces another compound, particularly a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may or may not be continuous.

As used herein, the term “gate all around transistor” may refer to devices which include a conductive material wrapped around a semiconductor channel region. As used herein, the term “gate all around transistor” may also refer to a variety of device architectures such as nanosheet devices, forksheet devices, vertical field effect transistors, stacked device architectures, etc.

The term “cyclic deposition process” or “cyclical deposition process” can refer to the sequential or spatial introduction of precursors into a reaction chamber to deposit a layer over a substrate and includes processing techniques such as atomic layer deposition (ALD), spatial atomic layer deposition (SALD), cyclical chemical vapor deposition (cyclical CVD), and hybrid cyclical deposition processes that may include an ALD component and a cyclical CVD component. In preferred embodiments, a cyclic deposition process as disclosed herein refers to an atomic layer deposition process.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). Generally, for ALD processes, during each cycle, a precursor is introduced to a reaction chamber and is chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, another precursor e.g. reactant may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber. Note that, as used herein, ALD processes are not necessarily comprised of a sequence of self-limiting surface reactions.

The standard abbreviations of the elements in the periodic table are used herein. Additionally, in certain places throughout the disclosure, the following abbreviations of groups may be used: “Me” stands for methyl (—CH₃); “Et” stands for ethyl (—CH₂CH₃); “nPr” stands for n-propyl (—CH₂CH₂CH₃); “iPr” stands for iso-propyl (—CH(CH₃)₂); “nBu” stands for n-butyl (—CH₂CH₂CH₂CH₃); “sBu” stands for sec-butyl (—CH(CH₃) CH₂CH₃), “iBu” stands for iso-butyl (—CH₂CH(CH₃) CH₃), “tBu” stands for tert-butyl (—C(CH₃)₃); “tPe” stands for tert-pentyl (—C(CH₃)₂CH₂CH₃), “Cp” stands for cyclopentadienyl (—C₅H₅), “Ph” stands for phenyl (—C₆H₅), and “BEN” stands for benzene.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

The presently described methods and devices may be useful for controlling the threshold voltage of field effect transistors. In some embodiments, the present methods and devices are particularly useful for controlling the threshold voltage of n-channel field effect transistors, such as n-channel metal-oxide semiconductor field effect transistors, such as n-channel gate-all-around metal oxide semiconductor field effect transistors. In some embodiments, the present methods and devices are particularly useful for controlling the threshold voltage of p-channel field effect transistors, such as p-channel metal-oxide semiconductor field effect transistors, such as p-channel gate-all-around metal oxide semiconductor field effect transistors. In some embodiments, the present methods and devices are particularly useful for inducing a negative flat band voltage shift for metal oxide semiconductor field effect transistors (MOSFETs). Thus, the present methods and devices may be particularly useful for decreasing the gate voltage at which a conductive channel is produced between the source and drain of an n-MOSFET. The n-MOSFET may, for example, be comprised in a CMOS-based integrated circuit. Additionally or alternatively, the present methods and devices may be particularly useful for increasing the gate voltage at which a conductive channel is produced between the source and drain of a p-MOSFET. The p-MOSFET may, for example, be comprised in a CMOS-based integrated circuit. In other words, the present methods and devices may be particularly useful for decreasing the voltage at which an n-MOSFET switches from an off-state to an on-state, and for increasing the voltage at which a p-MOSFET switches from an off-state to an on-state. Similarly, the present methods and devices may be particularly useful for decreasing the flat band voltage of n-MOSFETS, and for increasing the flat band voltage of p-MOSFETS. The presently methods and devices may be particularly useful for the manufacture of n-MOSFETS and p-MOSFETS with a gate-all-around architecture. Additionally or alternatively, the present methods and devices may be of particular use in the context of systems-on-a-chip. The metal carbide layers may be useful for front end of line (FEOL) applications, including as gate metal, as source/drain contact material, or as a component in threshold voltage (Vt) tuning layers.

In some embodiments, the present methods and devices are particularly useful for inducing a positive flatband voltage shift for metal oxide semiconductor field effect transistors (MOSFETs). Thus, the present methods and devices are particularly useful for increasing the gate voltage at which a conductive channel is produced between the source and drain of an n-MOSFET. The n-MOSFET may, for example, be comprised in a CMOS-based integrated circuit. Additionally or alternatively, the present methods and devices may be particularly useful for decreasing the gate voltage at which a conductive channel is produced between the source and drain of a p-MOSFET. The p-MOSFET may, for example, be comprised in a CMOS-based integrated circuit. In other words, the present methods and devices may be particularly useful for increasing the voltage at which an n-MOSFET switches from an off-state to an on-state, and for decreasing the voltage at which a p-MOSFET switches from an off-state to an on-state. Similarly, the present methods and devices may be particularly useful for increasing the flat band voltage of n-MOSFETS, and for decreasing the flat band voltage of p-MOSFETS. The presently described methods and devices may be particularly useful for the manufacture of n-MOSFETS and p-MOSFETS with a gate-all-around architecture. Additionally or alternatively, the present methods and devices may be of particular use in the context of systems-on-a-chip.

It shall be understood that when a metal carbide is abbreviated by means of a chemical formula, that chemical formula can indicate the metal carbide in the stoichiometry given, or in any other stoichiometry, including non-stoichiometric forms, depending, for example, on the oxidation state of the metal in question. For example, when titanium carbide is abbreviated as “TiC”, the term TiC can mean a titanium and carbon containing material in which titanium and carbon are present in a 1:1 ratio, or in any other suitable ratio, such as 0.8:1, 0.9:1, 0.95:1, 1:1.05, 1:1.1, 1:1.2, 1:1.5, etc. The percentage of Titanium atoms in the TiC may be between 70 to 150% of the number of carbon atoms in the layer. Other suitable metal carbides may be erbium carbide (ErC), cesium carbide (CeC), lanthanum carbide (LaC), molybdenum carbide (MoC) or tungsten carbide (WC).

Described herein are methods for depositing a metal carbide containing layer on a substrate. The methods comprise a step of providing a substrate in a reaction chamber. A suitable substrate includes a monocrystalline silicon wafer, e.g. a p-type monocrystalline silicon wafer. The substrate comprises a surface layer. The method further comprises a step of depositing a metal carbide containing layer onto the surface layer by means of a cyclical deposition process, such as an atomic layer deposition process or a cyclical chemical vapor deposition process. In some embodiments, the cyclical deposition process comprises one or more cycles. A cycle comprises two or more pulses. In some embodiments, at least one pulse involves a self-limiting surface reaction. In some embodiments, all pulses involve a self-limiting surface reaction. A cycle may comprise a first, second and third precursor pulses. A first precursor pulse may comprise a metal alkyl provided with a first metal; a second precursor pulse may comprise a halogenated hydrocarbon such as for example a dihaloalkane; and the third precursor may comprise a second metal different than the first metal. Thus, a metal carbide containing layer is formed on the substrate.

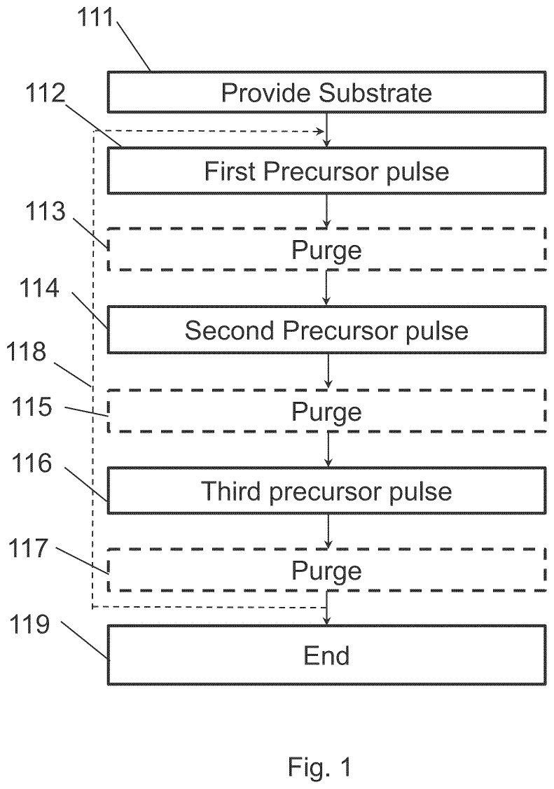

FIG. 1 illustrates a method in accordance with exemplary embodiments of the disclosure. This method can be used, for example, for depositing a metal carbide containing layer for use in a structure, such as a gate electrode, which is suitable for NMOS and/or CMOS devices. The present layers are particularly suitable for use as threshold voltage control layers in p- or n-channel MOSFETs. However, unless otherwise noted, methods are not limited to such applications. The method starts (111) after a substrate has been provided to a reaction chamber and involves depositing a metal carbide containing layer on the substrate by means of a cyclical deposition process that can be repeated (118) one or more times. The reaction chamber can be or include a reaction chamber of a chemical vapor deposition reactor system configured to perform a cyclical deposition process. Additionally or alternatively, the reaction chamber can be or can include a reaction chamber of an atomic layer deposition reactor system configured to perform a cyclical deposition process. The reaction chamber can be a standalone reaction chamber or part of a cluster tool. The reaction chamber may be part of a spatial atomic layer deposition (SALD) tool. In a SALD tool the precursor may be continuously provided. The precursors may be provided in regions spatially separated by purge regions. The substrate may be moved underneath the regions as to create different pulses of precursor to the surface of the substrate. The cyclical deposition process may comprise providing a first precursor (112) comprising a metal alkyl provided with a first metal in the reaction chamber. The process may comprise providing a second precursor (114) comprising a halogenated hydrocarbon, such as for example a dihaloalkane in the reaction chamber. The process may comprise providing a third precursor (116) comprising a second metal different than the first metal in the reaction chamber. In some embodiments, the method comprises a plurality of cycles, e.g. 2, 5, 10, or 20, or more cycles. In some embodiments, the method comprises from 1 to about 1,000 cycles. In some embodiments, the method comprises from 1 to about 500 cycles. In some embodiments, the method comprises from 1 to about 200 cycles. Optionally, the reaction chamber is purged (113) after the first precursor pulse (112). Optionally, the reaction chamber can be purged (115) after the second precursor pulse (114). Optionally, the reaction chamber can be purged (117) after the third precursor pulse (114). The first, second and third precursor pulses (112, 114, 116), and the optional purges (113,115, 117) can be repeated (118) any number of times to obtain a metal carbide containing layer having a desired thickness on the substrate in the reaction chamber. When a metal carbide containing layer having a desired thickness has been deposited, the method ends (119). Once the method has ended, the substrate can, for example, be subjected to additional processes to form a device structure and/or device.

In some embodiments, providing each of first precursor, second precursor and third precursor in the reaction chamber is performed only once. Each of the first precursor, second precursor and third precursor may be provided into the reaction chamber sequentially, with an optional intermittent purge step. Thus, in some embodiments, the method according to the current disclosure is acyclic process.

In an embodiment the metal alkyl of the first precursor may comprise an alkyl group comprising 1 to 6, preferably 1 to 4 carbon atoms. The alkyl group may comprise a methyl or an ethyl group.

In an embodiment, the first precursor may have a first metal comprising aluminum (Al). The first precursor may be trimethylaluminum (TMA; AlMe₃). In an embodiment the first precursor may be tricthylaluminum (AlEt₃). In another embodiment the first precursor may be dimethyl-tert-butyl-aluminum (Al(CH₃)₂(C(CH₃)₃)), or tetramethyl-di-tert-butylaluminum (Al₂(CH₃)₄((C(CH₃)₃)₂) in dimeric or monomeric form.

In an embodiment, the first precursor may have a first metal comprising zinc (Zn). The first precursor may be dimethylzinc (ZnMe₂). In an embodiment the first precursor may be diethylzinc (ZnEt₂).

In an embodiment, the first precursor may comprise gallium (Ga) or indium (In).

In an embodiment, the second precursor comprising the halogenated hydrocarbon comprises iodine or bromine as the halogen.

In an embodiment the halogenated hydrocarbon may comprise a dihaloalkane and the halogen atoms may be on the same carbon atom, on adjacent carbon atoms, or on two carbon atoms separated by at least one carbon atom.

In an embodiment the halogenated hydrocarbon comprises 1 to 10 carbon atoms and one or more halogen atoms. The halogenated hydrocarbon may be iodoalkane or bromoalkane. The halogenated hydrocarbon may be a monohaloalkane such as for example monoiodoalkane or monobromoalkane. Examples of monohaloalkanes are iodomethane, iodocthane, iodopropane, iodobutane, iodo-tert-butane, iodo-sec-butane, iodo-isobutane, bromomethane, bromoethane, bromopropane, bromobutane, bromo-tert-butane, bromo-sec-butane and bromo-isobutane. Further examples of monohaloalkanes are iodopentane, iodohexane, bromopentane and bromohexane including their branched isomers. The halogenated hydrocarbon may be a dihaloalkane such as for example diiodoalkane or dibromoalkane. Examples of monohaloalkanes are diiodomethane, diiodocthane, diiodopropane, diiodobutane, diiodo-tert-butane, diiodo-sec-butane, diiodo-isobutane, dibromomethane, dibromoethane, dibromopropane, dibromobutane, dibromo-tert-butane, dibromo-sec-butane and dibromo-isobutane. Further examples of dihaloalkanes are diiodopentane, diiodohexane, dibromopentane and dibromohexane, including their branched isomers. For example, the halogenated hydrocarbon may be 1,1-diiodocthane, 1,2-diiodocthane, 1,1-diiodopropane, 1,2-diiodopropane, 1,3-diiodopropane, 1,1-dibromoethane, 1,2-dibromoethane, 1,1-dibromopropane, 1,2-dibromopropane or 1,3-dibromopropane. In some embodiments, the halogenated hydrocarbon comprises at least three halogen atoms. Thus, it may be a trihaloalkane, tetrahaloalkane, or pentahaloalkane, for example.

In an embodiment the halogenated hydrocarbon may comprise an aromatic hydrocarbon. The aromatic hydrocarbon may be iodobenzene, diiodobenzene, bromobenzene or dibromobenzene, for example. The aromatic hydrocarbon may comprise a diiodobenzene selected from the group of 1,2-diiodobenzene, 1,3-diiodobenzene, and 1,4-diiodobenzene. The aromatic hydrocarbon may comprise a dibromobenzene selected from the group of 1,2-dibromobenzene, 1,3-dibromobenzene, and 1,4-dibromobenzene. The benzene ring may comprise additional substituents, such as one or more alkyl groups, e.g. methyl, ethyl or propyl groups. In some embodiments, the benzene ring has no other substituents other than the one or more halogen atoms. In some embodiments, the benzene ring has at least one alkyl substituent in addition to the one or more halogen atoms.

In embodiments, in which the halogenated hydrocarbon comprises two or more halogen atoms, the two halogen atoms may be attached to the same or different carbon atoms. In some embodiments, the halogen atoms are attached to adjacent carbon atoms. In some embodiments, the halogen atoms are attached to non-adjacent carbon atoms. In other words, there is at least one carbon atom between two carbon atoms to which a halogen atom is attached.

In certain embodiments, the reaction mechanism may proceed for example as follows: AlMe₃ of the first precursor chemisorbed to the surface of the substrate may react with the alkyl halide of the second precursor to generate (α-iodoalkyl)aluminum species bound to the surface of the substrate. The surface-bound (α-iodoalkyl)aluminum species may react with the third precursor comprising a second metal different than the first metal to form a metal carbide.

In an embodiment, the third precursor may comprise a second metal comprising a rare earth metal. In an embodiment the rare earth metal may comprise Scandium (Sc) or Yttrium (Y). In an embodiment, the rare earth metal may comprise one or more of the following lanthanides; lanthanum (La), cerium (Ce), praseodymium (Pr), neodymium (Nd), samarium (Sm), curopium (Eu), gadolinium (Gd), terbium (Tb), dysprosium (Dy), holmium (Ho), erbium (Er), thulium (Tm), ytterbium (Yb), and lutetium (Lu).

In an embodiment the third precursor comprising the second metal may comprise one or more of the following ligands: arene, cyclopentadienyl, amidinate, amidate, beta-diketonate, pyrazolate, dialkyltriazenide, dialkylaminodiboronate, and hexamethyldisilazide. In some embodiments, in which the ligand is arene, the metal is not a rare earth metal. For example, molybdenum, niobium and vanadium may form a suitable third precursor comprising an arene ligand.

In an embodiment, the second metal may be selected from group 4, 5, 6 or 7 of the periodic table of elements. The second metal may be selected from the group of titanium (Ti), zirconium (Zr), hafnium (Hf), vanadium (V), niobium (Nb), tantalum (Ta), chromium (Cr), molybdenum (Mo), tungsten (W), manganese (Mn), and rhenium (Re).

In an embodiment, the third precursor may comprise nitrogen. The nitrogen may escape or remain in the metal carbide layer on the surface of the substrate. A metal carbide according to the current disclosure may comprise other elements, such as nitrogen, phosphorus or sulfur. Without limiting the current disclosure to any specific theory, the composition of the deposition surface may influence the composition of the metal carbide deposited according to the current disclosure.

In an embodiment, the metal alkyl of the first precursor may be trimethylaluminum (TMA) and the halogenated hydrocarbon of the second precursor may be a dihaloalkane such as for example diiodomethane. In this way readily available precursors in the semiconductor industry may be used.

In an embodiment, the third precursor may be tris(N,N′-diisopropylformamidinato)lanthanum(III). This precursor may be abbreviated as La(famd)₃. In an embodiment, the third precursor may be tris(isopropylcyclopentadienyl) lanthanum. This precursor may be abbreviated as La(iPrCp)₃. In an embodiment, the third precursor may be tris(ethylcyclopentadienyl) lanthanum. This precursor may be abbreviated as La(EtCp)₃.

In an embodiment, the third precursor may be tris(methylcyclopentadienyl) yttrium (III). This precursor may be abbreviated as Y(MeCp)₃. In an embodiment, the third precursor may be tris(ethylcyclopentadienyl)yttrium (III). This precursor may be abbreviated as Y(EtCp)₃. In an embodiment, the third precursor may be tris(butylcyclopentadienyl) yttrium (III). This precursor may be abbreviated as Y(BuCp)₃.

In an embodiment, the third precursor may be tris(isopropylcyclopentadienyl) scandium. This precursor may be abbreviated as Sc(iPrCp)₃. In an embodiment, the third precursor may be tris(methylcyclopentadienyl) scandium. This precursor may be abbreviated as Sc (MeCp)₃. In an embodiment, the third precursor may be tris(isopropylcyclopentadienyl) cerium. This precursor may be abbreviated as Ce (iPrCp)₃.

In an embodiment a system for depositing metal carbide is provided. The system may comprise:
a reaction chamber,
a first gas source for providing a first gas comprising a metal alkyl provided with a first metal in the reaction chamber;
a second gas source for providing a second precursor comprising a halogenated hydrocarbon in the reaction chamber;
a third precursor gas source for providing a third precursor comprising a second metal different than the first metal in the reaction chamber; and,
a controller to control the flow of gas from the first, second and third precursor gas source to the reaction chamber, the system being constructed and arranged for carrying out a method as mentioned before in the reaction chamber.

In an embodiment a structure comprising a stack of layers is provided. The stack may have in the following order: a first conductive layer, a metal carbide containing layer, and a second conductive layer. The metal carbide layer may be deposited using the method as mentioned before.

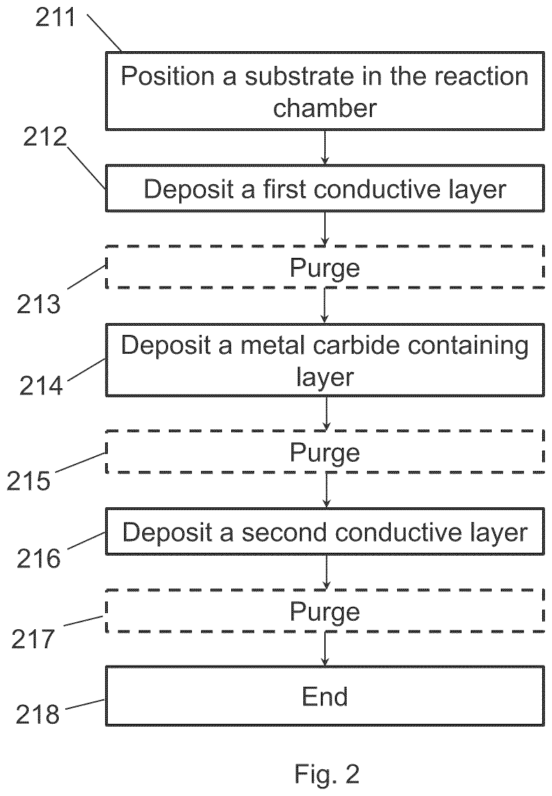

FIG. 2 illustrates another method in accordance with exemplary embodiments of the disclosure. This method can be used to, for example, form a structure e.g. a gate electrode structure for a metal oxide semiconductor field effect transistor. The method of FIG. 2 comprises positioning a substrate on a substrate support in a reaction chamber (211). The method further comprises depositing a first conductive layer (212). Optionally, the method then comprises purging the reaction chamber (213). Then, the method comprises depositing a metal carbide containing layer on the first conductive layer (214). Optionally, the method then comprises purging the reaction chamber (215). Then, the method comprises depositing a second conductive layer on the metal carbide containing layer (216). Optionally, the method then comprises purging the reaction chamber (217). The process according to FIG. 2 may comprise additional phases or subprocesses, depending on the specific structure in question. Exemplary phases or subprocesses may include cleaning, etch-back, doping or the like. Then, the method ends (218). Once the method has ended, the substrate can, for example, be subjected to additional processes to form a device structure and/or device. Note the first and the second conductive layers can comprise any conductive material, such as a metal or a nitride or a carbide, for example a transition metal nitride such as TiN, a transition metal such as Ti, or a transition metal carbide such as TiC. Optionally, the process according to FIG. 2 may be followed by a thermal treatment step, such as a forming gas anneal or a rapid thermal anneal.

It shall be understood that in a method according to FIG. 2, the metal carbide containing layer can be deposited using a cyclical deposition process as disclosed herein. The cyclical deposition process can include cyclical CVD, ALD, a hybrid cyclical CVD/ALD or spatial ALD process. Preferably, the cyclical deposition process employs reaction conditions which, when combined with a selected precursors, allow for self-limiting surface reactions to occur. For example, in some embodiments, the growth rate of a particular ALD process may be low compared with a CVD process.

Any one of the methods according to FIG. 1 or FIG. 2 may include heating the substrate to a desired deposition temperature within the reaction chamber. In some embodiments of the disclosure, the method includes heating the substrate to a temperature of less than 500° C. For example, in some embodiments of the disclosure, heating the substrate to a deposition temperature may comprise heating the substrate to a temperature of at least 100° C. to at most 400° C., or at a temperature of at least 150° C. to at most 350° C., or at a temperature of at least 200° C. to at most 300° C. In addition to controlling the temperature of the substrate, a pressure within the reaction chamber may also be regulated. For example, in some embodiments of the disclosure, the pressure within the reaction chamber during the cyclical deposition process may be less than 760 Torr or between 0.2 Torr and 760 Torr, about 1 Torr and 100 Torr, or about 1 Torr and 10 Torr.

Any one of the methods according to FIG. 1, or 2 may comprise one or more purges. During a purge, the reaction chamber can be purged using a vacuum and/or an inert gas to mitigate gas phase reactions between precursors and reactants and enable partly or fully self-saturating surface reactions—e.g., in the case of ALD. Additionally or alternatively, the substrate may be moved to separately contact a first vapor phase reactant, e.g. a precursor, and a second vapor phase reactant, e.g. a reactant. Additionally or alternatively, gaseous species may be removed from the reaction chamber during any one of the purges by mean of a gas removal device such as a pump. Surplus chemicals and reaction byproducts, if any, can be removed from the substrate surface or reaction chamber, such as by purging the reaction space or by moving the substrate before the substrate is contacted with the next reactive chemical.

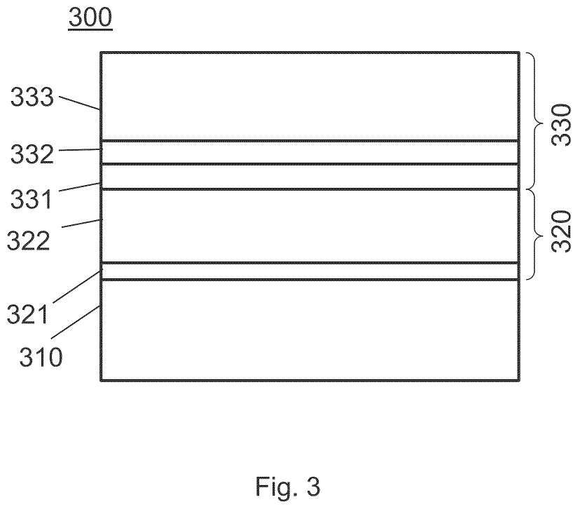

FIG. 3 illustrates a structure/a portion of a device (300) in accordance with additional examples of the disclosure. The device or structure (300) includes a substrate (310), dielectric or insulating material, i.e. a gate dielectric (320), and a gate electrode (330). The substrate (300) can be or include any of the substrate material described herein. The gate dielectric (320) can include one or more dielectric or insulating material layers. By way of example, the gate dielectric (320) can include an interfacial layer (321) and a high-k material (322) deposited overlying the interfacial layer (321). In some cases, the interfacial layer (321) may not exist or may not exist to an appreciable extent. The interfacial layer (321) may include an oxide, such as a silicon oxide, which can for example be formed on a, for example monocrystalline silicon, surface of the substrate (310) using, for example, a chemical oxidation process or an oxide deposition process. The high-k material (322) can be or include, for example, a metal oxide having a dielectric constant greater than about 7. In some embodiments, the high-k material has a dielectric constant higher than the dielectric constant of silicon oxide. Exemplary high-k materials include hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃), yttrium oxide (Y₂O₃) or lanthanum oxide (La₂O₃), mixtures thereof, and laminates thereof. The gate electrode (330) comprises a first conductive layer (331), a metal carbide containing layer (332), and a second conductive layer (333). Those layers and deposition methods for forming those layers are described in more detail elsewhere herein. In an exemplary embodiment, at least one of the first conductive layer (331) and the second conductive layer (333) comprises titanium nitride, and the metal carbide containing layer (332) comprises cerium carbide.

An effective work function of a gate electrode (330) comprising a metal carbide containing layer (332) can vary from at least 4.0 eV to at most 5.6 cV. An effective work function of a gate stack can be shifted by about 10 meV to about 600 meV, or about 30 meV to about 300 meV, or about 50 meV to about 200 me V using metal carbide containing layer as described herein.

A metal carbide containing layer (332) can form a continuous film at a thickness of less than 10 nm, <5 nm, <4 nm, <3 nm, <2 nm, <1.5 nm, <1.2 nm, <1.0 nm, or <0.9 nm. The metal carbide containing layer (332) can be relatively smooth, with relatively low grain boundary formation. In some cases, the metal carbide containing layer (332) may be at least partially amorphous. In some embodiments, the metal carbide containing layer (332) can be entirely or substantially entirely amorphous. The Root Mean Square (RMS) roughness of an exemplary metal carbide containing layer (332) can be <1.0 nm, <0.7 nm, <0.5 nm, <0.4 nm, <0.35 nm, or <0.3 nm, at a thickness of less than 10 nm.

In some embodiments, the metal carbide containing layer (332) may comprise isolated islands, gaps, and/or holes. The metal carbide containing layer (332) may even entirely consist of a plurality of isolated atoms and/or clusters of atoms.

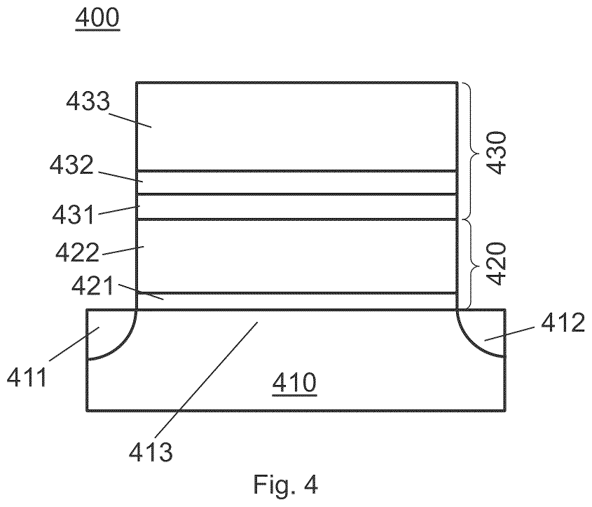

FIG. 4 illustrates another exemplary structure (400) in accordance with examples of the disclosure. The device or structure (400) may include a substrate (410), a gate dielectric (420), and a gate electrode (430). The gate dielectric (420) comprises an interfacial layer (421) and a high-k dielectric layer (422). A suitable interfacial layer includes silicon oxide. The structure further may comprise a gate electrode (430) comprising a first conductive layer (431), a metal carbide containing layer (432), and a second conductive layer (433). In the illustrated example, the substrate (410) includes a source region (411), a drain region (412), and a channel region (413). By applying bias, i.e. a negative or positive voltage, to the gate electrode (430), a conductive channel between the source region (411) and the drain region (412) can be formed in the channel region (413). The nature of the gate dielectric (420) and the gate electrode (430), in particular the nature of the metal carbide containing layer determines the voltage at which this channel becomes conductive. Although illustrated as a horizontal structure, structures and devices in accordance with examples of the disclosure can include vertical and/or three-dimensional structures and devices, such as FinFET devices, gate-all-around field effect transistors, and stacked device architectures.

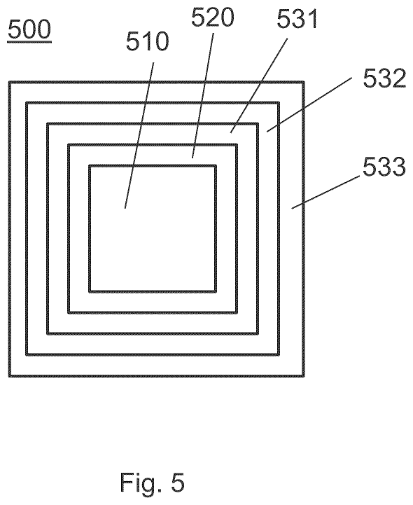

FIG. 5 illustrates another structure (500) in accordance with examples of the disclosure. This structure (500) is suitable for gate all around field effect transistors (GAA FETs) (also referred to as lateral nanowire FETs) devices and the like. In the illustrated example, the structure (500) may include a semiconductor material, i.e. a channel region (510) and a gate dielectric (520) surrounding the channel region (520). The structure (500) further may comprise a gate electrode surrounding the gate dielectric (520). The gate electrode comprises a first conductive layer (531), a metal carbide containing layer (532) as described herein, and a second conductive layer (533). The channel region (520) can include any suitable semiconducting material. For example, the semiconductor material can include Group IV, Group III-V, or Group II-VI semiconductor material. By way of example, the semiconductor material includes silicon, or more specifically monocrystalline silicon.

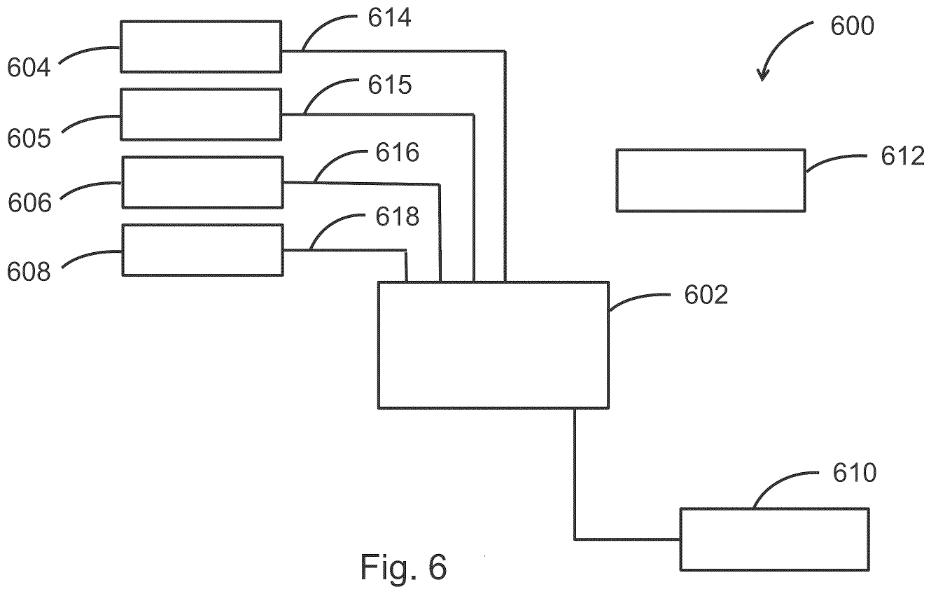

FIG. 6 illustrates a system (600) in accordance with yet additional exemplary embodiments of the disclosure. The system (600) can be used to perform a method as described herein and/or form a structure or device portion as described herein.

In the illustrated example, the system (600) includes one or more reaction chambers (602), precursor gas sources (604), (605), (606), a purge gas source (608), an exhaust (610), and a controller (612). The reaction chamber (602) can include any suitable reaction chamber, such as an ALD or CVD reaction chamber. Optionally, the system (600) comprises further gas sources such as an optional hydrogen containing gas source (not shown).

The first precursor gas source (604), the second precursor gas source (605), and the third precursor gas source (606) can include a vessel and one or more precursors as described herein-alone or mixed with one or more carrier (e.g., inert) gases. The purge gas source (608) can include one or more inert gases such as N₂ or a noble gas, as described herein. The system (600) can include any suitable number of gas sources. The gas sources (604)-(608) can be coupled to reaction chamber (602) via lines (614)-(618), which can each include flow controllers, valves, heaters, and the like. The exhaust (610) can include one or more vacuum pumps.

The controller (612) may include electronic circuitry and software to selectively operate valves, manifolds, heaters, pumps and other components included in the system (600). Such circuitry and components operate to introduce precursors, reactants, and purge gases from the respective sources (604)-(608). The controller (612) can control timing of gas pulse sequences, temperature of the substrate and/or reaction chamber, pressure within the reaction chamber, and various other operations to provide proper operation of the system (600). The controller (612) may include control software to electrically or pneumatically control valves to control flow of precursors, reactants and purge gases into and out of the reaction chamber (602). The controller (612) can include modules such as a software or hardware component, e.g., a FPGA or ASIC, which performs certain tasks. A module can advantageously be configured to reside on the addressable storage medium of the control system and be configured to execute one or more processes.

Other configurations of the system (600) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber (602). Further, as a schematic representation of a system, many components have been omitted for simplicity of illustration, and such components may include, for example, various valves, manifolds, purifiers, heaters, containers, vents, and/or bypasses.

During operation of the reactor system (600), substrates, such as semiconductor wafers (not illustrated), are transferred from, e.g., a substrate handling system to the reaction chamber (602). Once substrate(s) are transferred to the reaction chamber (602), one or more gases from the gas sources (604)-(608), such as precursors, reactants, carrier gases, and/or purge gases, may be introduced into reaction chamber (602) to form a metal carbide layer on the substrate.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for depositing metal carbide on a substrate, the method comprising:
providing a substrate in a reaction chamber;
providing a first precursor comprising a metal alkyl provided with a first metal in the reaction chamber;
providing a second precursor comprising a halogenated hydrocarbon in the reaction chamber; and
providing a third precursor comprising a second metal different than the first metal in the reaction chamber, thereby forming a metal carbide layer on the substrate in the reaction chamber.

2. The method according to claim 1, wherein the first metal is selected from the group consisting of aluminum, zinc, gallium, and indium.

3. The method according to claim 1, wherein the metal alkyl comprises an alkyl group that comprises 1 to 6 carbon atoms.

4. The method according to claim 1, wherein the metal alkyl comprises a methyl group or an ethyl group.

5. The method according to claim 1, wherein the halogenated hydrocarbon comprises a halogen selected for the group of iodine and bromine as the halogen.

6. The method according to claim 1, wherein the halogenated hydrocarbon comprises a dihaloalkane and the halogen atoms are on the same carbon atom, on adjacent carbon atoms, or on two carbon atoms separated by at least one carbon atom.

7. The method according to claim 1, wherein the halogenated hydrocarbon comprises 1 to 10 carbon atoms and one or more halogen atoms.

8. The method according to claim 1, wherein the halogenated hydrocarbon comprises an aromatic hydrocarbon.

9. The method according to claim 8, wherein the aromatic hydrocarbon comprises a diodobenzene selected from the group of 1, 2-; 1, 3-; and 1, 4-substituted diodobenzenes.

10. The method according to claim 1, wherein the second metal comprises a rare earth metal.

11. The method according to claim 10, wherein the rare earth metal comprises scandium (Sc) or yttrium (Y).

12. The method according to claim 1, wherein the second metal comprises one or more of the following ligands: arene, cyclopentadienyl, amidinate, amidate, beta-diketonate, pyrazolate, dialkyltriazenide, dialkylaminodiboronate, and hexamethyldisilazide.

13. The method according to claim 1, wherein the second metal comprises a metal from group 4, 5, 6, or 7 of the periodic table of elements.

14. The method according to claim 1, wherein the third precursor comprises nitrogen.

15. The method according to claim 1, wherein the metal alkyl is trimethylaluminum and the dihaloalkane is diiodomethane or diodoethane.

16. The method according to claim 1, wherein the third precursor comprises tris(N,N′-diisopropylformamidinato) lanthanum (III).

17. The method according to claim 1, wherein the third precursor comprises tris(methylcyclopentadienyl) yttrium (III).

18. The method according to claim 1, wherein the method is an atomic layer deposition method wherein the first, second and third precursors are provided sequentially, and an inert gas is provided in between each step of providing the first, second and third precursors.

19. A system for depositing metal carbide, the system comprising:
a reaction chamber,
a first gas source for providing a first gas comprising a metal alkyl provided with a first metal in the reaction chamber;
a second gas source for providing a second precursor comprising a halogenated hydrocarbon in the reaction chamber;
a third precursor gas source for providing a third precursor comprising a second metal different than the first metal in the reaction chamber; and,
a controller to control the flow of gas from the first, second and third precursor gas sources to the reaction chamber, the system being constructed and arranged for carrying out a method according to claim 1 in the reaction chamber.

20. A structure comprising a stack of layers, in the following order: a first conductive layer, a metal carbide containing layer, and a second conductive layer, wherein the metal carbide layer is deposited using the method according to claim 1.
